(19) United States
(12) Patent Application Publication
(10) Pub. No.: US 2021/0384432 A1
(43) Pub. Date: Dec. 9, 2021

(54) LAMINATION TOOL AND LAMINATION METHOD FOR FLEXIBLE DISPLAY PANEL

(71) Applicants: Chengdu BOE Optoelectronics Technology Co., Ltd., Chengdu, Sichuan (CN); BOE Technology Group Co., Ltd., Beijing (CN)

(72) Inventors: Shaokui LIU, Beijing (CN); Qiang TANG, Beijing (CN); Wei QING, Beijing (CN); Xingguo LIU, Beijing (CN)

(21) Appl. No.: 17/290,300

(22) PCT Filed: Jun. 28, 2020
(86) PCT No.: PCT/CN2020/098619

§ 371 Date: Apr. 30, 2021

(30) Foreign Application Priority Data
Jul. 31, 2019 (CN) 201910703823.3

(51) Int. Cl. H01L 51/00; H01L 51/56; G09F 9/30

(52) U.S. Cl. CPC H01L 51/0024; G09F 9/301; H01L 51/0097; H01L 51/56

(57) ABSTRACT

Disclosed in embodiments of the present disclosure are a lamination tool and a lamination method for a flexible display panel. The lamination tool for a flexible display panel includes: a flexible substrate, the flexible substrate including a flat portion located at a middle position and a deformation portion located at an edge position, the deformation portion including a tightened state and an expanded state, when the deformation portion is in the tightened state, same is used for carrying the flexible display panel to be laminated, and when the deformation portion is in the expanded state, same is used for laminating the edge of the flexible display panel and a cover plate; a pre-fixing device for pre-fixing the flexible display panel to be laminated; a first press-fitting assembly acting on the flat portion of the flexible substrate; and second press-fitting assemblies acting on the deformation portion of the flexible substrate.

### CROSS REFERENCE TO RELATED APPLICATION

The present disclosure is a National Stage of International Application No. PCT/CN2020/098619, filed Jun. 28, 2020, which claims the priority from Chinese Patent Application No. 201910703823.3, filed with the China National Intellectual Property Administration on Jul. 31, 2019 and entitled “Lamination tool and Lamination Method for Flexible Display Panel”, the entire content of which is hereby incorporated by reference.

### FIELD

The present disclosure relates to the technical field of display device, in particular to a lamination tool and lamination method for a flexible display panel.

### BACKGROUND

At present, Organic Light-Emitting Diode, OLED, flexible display panels have been widely used in various electronic products as display components for electronic devices. With the development of curved screens, the shape of the glass cover plate attached to the outside of an OLED flexible display panel is becoming more and more diversified, and the glass cover plate with a large arc and inverted shape has become a new trend. The current vacuum lamination technology can only satisfy the lamination between the non-inverted large arc glass cover plate and the OLED flexible display panel, and cannot realize full lamination between the large arc and inverted glass cover plate and the OLED flexible display panel.

### SUMMARY

Embodiments of the present disclosure provide a lamination tool for a flexible display panel, including:

a flexible substrate, one surface of the flexible substrate serving as a bearing surface;

the flexible substrate includes: a flat portion located at a middle position of the flexible substrate; and a deformation portion located at an edge position of the flexible substrate, and the deformation portion is switched between a tightened state and an expanded state;

a pre-fixing device, configured to fix a to-be-laminated flexible display panel on the bearing surface of the flexible substrate and bend the to-be-laminated flexible display panel into a shape same as a shape of the bearing surface when the deformation portion of the flexible substrate is in the tightened state;

a first press-fitting assembly, configured to act on the flat portion of the flexible substrate to laminate a center of the to-be-laminated flexible display panel with a cover plate; and

a second press-fitting assembly, configured to act on the deformation portion of the flexible substrate and laminate an edge of the to-be-laminated flexible display panel with the cover plate when the deformation portion changes from the tightened state to the expanded state.

In some embodiments, the flexible substrate is a silicone flexible substrate.

In some embodiments, a thickness of the deformation portion is less than a thickness of the flat portion, and the bearing surface of the flexible substrate is a smooth surface.

Optionally, in the above lamination tool for the flexible display panel provided in embodiments of the present disclosure, the pre-fixing device includes a bearing film and a driving piece;

one surface of the bearing film is bonded with the to-be-laminated flexible display panel, and the other surface of the bearing film is bonded with the bearing surface of the flexible substrate; and

the driving piece is configured to be used in conjunction with the bearing film and drive the bearing film to bend through stretching the bearing film.

In some embodiments, the first press-fitting assembly includes a hydraulic column acting on the flat portion.

In some embodiments, the second press-fitting assembly includes an airbag acting on the deformation portion, an air inlet valve configured to inflate the airbag and an air outlet valve configured to deflate the airbag.

In some embodiments, a transition area is located between the flat portion and the deformation portion of the flexible substrate; and

a thickness of a portion, corresponding to the transition area, in the airbag is less than a thickness of another portion in the airbag.

In some embodiments, the air inlet valve is a rotatable air inlet valve, and after an air outlet of the rotatable air inlet valve is rotated, the air outlet blows air directionally towards the portion, corresponding to the transition area, in the airbag.

On another hand, embodiments of the present disclosure further provide a lamination method for a flexible display panel, including:

fixing a to-be-laminated flexible display panel to a bearing surface of a flexible substrate with the deformation portion being in a tightened state through a pre-fixing device;

controlling the first press-fitting assembly to act, to laminate the portion, corresponding to the flat portion of the flexible substrate, of the to-be-laminated flexible display panel with a middle position of a cover plate; and

controlling the second press-fitting assembly to act, to change the deformation portion of the flexible substrate from a tightened state to an expanded state, and the portion, corresponding to the deformation portion, of the to-be-laminated flexible display panel is laminated with an edge position of the cover plate.

In some embodiments, the above lamination method of the flexible display panel further includes:

controlling the second press-fitting assembly to act, to keep the deformation portion away from the cover plate; and

controlling the first press-fitting assembly to act, to keep the flexible substrate away from the cover plate.

In some embodiments, the controlling the second press-fitting assembly to act, to change the deformation portion of the flexible substrate from the tightened state to the expanded state, and the portion, corresponding to the deformation portion, of the to-be-laminated flexible display panel is laminated with the edge position of the cover plate includes:

controlling a rotatable air inlet valve to inflate an airbag, the airbag is gradually expanded to enable the deformation portion of the flexible substrate to change from the tightened state to the expanded state, to pre-laminated the edge position of the to-be-laminated flexible display panel with the edge position of the cover plate; and

rotating an air outlet of the rotatable air inlet valve, and blowing air towards the portion, corresponding to the transition area of the flexible substrate, in the airbag, to fully laminated the edge position of the to-be-laminated flexible display panel with the edge position of the cover plate.

### BRIEF DESCRIPTION OF THE DRAWINGS

FIG. 1 is a structural schematic diagram of a lamination tool for a flexible display panel, provided by an embodiment of the present disclosure;

FIG. 2 is a partial structural schematic diagram when a to-be-laminated flexible display panel is prefixed through a lamination tool for a flexible display panel, provided by an embodiment of the present disclosure;

FIG. 3 is a partial structural schematic diagram, when a first press-fitting assembly is act, of a lamination tool for a flexible display panel, provided by an embodiment of the present disclosure acts;

FIG. 4 is a partial structural schematic diagram, when a second press-fitting assembly is act, of a lamination tool for a flexible display panel, provided by an embodiment of the present disclosure, laminates the edge of the to-be-laminated flexible display panel with the cover plate;

FIG. 5 is a partial structural schematic diagram after a lamination tool for a flexible display panel, provided by an embodiment of the present disclosure, laminates the to-be-laminated flexible display panel with a cover plate;

FIG. 6 is a schematic diagram of a lamination method for a flexible display panel, provided by an embodiment of the present disclosure.

### DETAILED DESCRIPTION OF THE EMBODIMENTS

A clear and complete description will be given below on technical solutions in embodiments of the present disclosure in combination with accompanying drawings in embodiments of the present disclosure. Obviously, the described embodiments are merely part but not all of embodiments of the present disclosure. Based on embodiments of the present disclosure, all the other embodiments obtained by those skilled in the art without any creative effort shall all fall within the protection scope of the present disclosure.

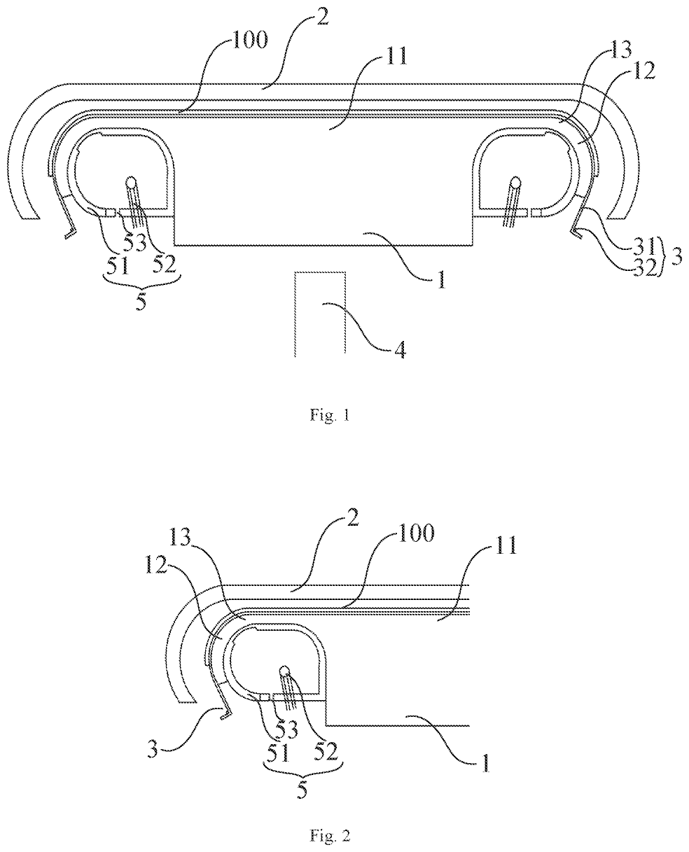

Refer to FIG. 1, the present disclosure provides a lamination tool for a flexible display panel, configured to laminate a cover plate 2 with a to-be-laminated flexible display panel 100, including:

a flexible substrate 1 configured to bear a to-be-laminated flexible display panel 100, one surface of the flexible substrate 1 serves as a bearing surface, the flexible substrate 1 includes a flat portion 11 located at a middle position of the flexible substrate 1 and a deformation portion 12 located at an edge position of the flexible substrate 1, and the deformation portion 12 is switched between a tightened state and an expanded state, that is, the deformation portion 12 includes a tightened state and an expanded state. When the deformation portion 12 is in the tightened state, the deformation portion 12 is configured to bear the to-be-laminated flexible display panel 100, and when the deformation portion 12 is in the expanded state, the deformation portion 12 is configured to laminate the edge of the to-be-laminated flexible display panel 100 with the cover plate 2;

a pre-fixing device 3, configured to fix a to-be-laminated flexible display panel on the bearing surface of the flexible substrate 1 and bend the to-be-laminated flexible display panel 100 into a shape same as a shape of the bearing surface when the deformation portion 12 of the flexible substrate 1 is in the tightened state;

a first press-fitting assembly 4, configured to act on the flat portion 11 of the flexible substrate 1 to laminate a center of the to-be-laminated flexible display panel 100 with a cover plate 2 through the flexible substrate 1; and

a second press-fitting assembly 5, configured to act on the deformation portion 12 of the flexible substrate 1 and laminate an edge of the to-be-laminated flexible display panel with the cover plate 2 through enabling the deformation portion 12 of the flexible substrate 1 to change from the tightened state to the expanded state.

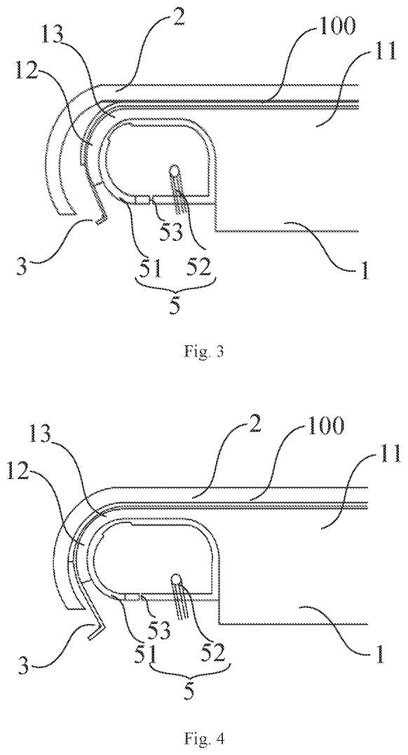

In some embodiments, as shown in FIG. 2, firstly the to-be-laminated flexible display panel 100 is fixed on the bearing surface of the flexible substrate 1 through a pre-fixed device 3, and then the to-be-laminated flexible display panel 100 is bent to have the same shape as the bearing surface, at this time, the deformation portion 12 of the flexible substrate 1 is in the tightened state, the to-be-laminated flexible display panel 100 is laminated with the bearing surface of the flexible substrate 1, and the surface, facing away from the bearing surface, of the to-be-laminated flexible display panel 100 has optical adhesive, and the flexible display panel and the cover plate are fixed through optical adhesive in the subsequent laminating process. Then as shown in FIG. 3, when the first press-fitting assembly 4 acts on the surface, facing away from the bearing surface, of the flat portion 11 of the flexible substrate 1, the middle position of the to-be-laminated flexible display panel is laminated with the cover plate 2. Then as shown in FIG. 4, when the second press-fitting assembly 5 acts on the surface, facing away from the bearing surface, of the deformation portion 12 of the flexible substrate 1, the deformation portion 12 changes from the tightened state to the expanded state, such that the edge position of the to-be-laminated flexible display panel is laminated with the cover plate 2, to complete lamination. Finally, as shown in FIG. 5, the pretightening force of the pre-fixing device 3 is removed, the first press-fitting assembly 4 moves away from the cover plate 2, and the lamination tool is separated from the laminated display device.

In some embodiments, the to-be-laminated flexible display panel 100 is in contact with the cover plate 2 from the middle position to the edge position, such that the large arc inverted or large arc long glass cover plate 2 is fully laminated with the flexible display panel, therefore, the lamination tool is simple and practical, moreover, the laminating pressure can be controlled through the first press-fitting assembly 4 and the second press-fitting assembly 5, such that in the laminating process, the risk of generating bubbles and cracks is small, and the laminating effect is better.

In some embodiments, the flexible substrate 1 can be a silicone flexible substrate 1. In some embodiments, the flexible substrate 1 adopts silicone material which is easily available, moreover, the flexible substrate 1 of the silicone material can enable the to-be-laminated flexible display panel 100 to be well laminated with the cover plate 2, and the deformed effect of a deformation portion 12 of the silicone flexible substrate 1 is favorable, thereby realizing good lamination between the edge position of the to-be-laminated flexible display panel 100 and the cover plate 2.

In some embodiments, as shown in FIG. 1, a thickness of the deformation portion 12 of the flexible substrate 1 is generally less than a thickness of the flat portion 11, and the bearing surface of the flexible substrate 1 is a smooth surface. In some embodiments, the thickness of the deformation portion 12 of the flexible substrate 1 is set to be less than the thickness of the flat portion 11, and stepped transition of thickness occurs on a surface, facing away from the bearing surface, of the flexible substrate 1, such that the deformation portion 12 is bent towards the side facing away from the bearing surface, the bending effect is better when the deformation portion 12 is set to be in the tightened state. Moreover, to accommodate the curved display screen, generally, the flexible substrate 1 is provided with two deformation portions 12 which are respectively located at two opposite sides of the flat portion 11.

In some embodiments, as shown in FIG. 1 and FIG. 5, the pre-fixing device 3 includes a bearing film 31 and a driving piece 32, one surface of the bearing film 31 is bonded with the to-be-laminated flexible display panel 100, and the other surface of the bearing film 31 is bonded with the bearing surface of the flexible substrate 1; and a driving piece 32 configured to be used in conjunction with the bearing film 31 and drive the bearing film 31 to bend through stretching the bearing film 31. In some embodiments, in the laminating process, firstly the to-be-laminated flexible display panel 100 is pasted on the bearing film 31, and is placed on the bearing surface of the flexible substrate 1 and drives the bearing film 31 through the driving piece 32 to realize pre-bending forming. The bearing film 31 is placed on a surface, facing towards the bearing surface, of the to-be-laminated flexible display panel 100, and one surface, facing away from the bearing surface, of the to-be-laminated flexible display panel 100 is coated with colloid to laminate the to-be-laminated flexible display panel 100 with the cover plate 2. The material of the colloid can be optical adhesive and can also be other colloid, which is not defined herein. Moreover, to prevent failed lamination caused by contact in advance between the to-be-laminated flexible display panel 100 and the cover plate 2 in the upward movement process of the flexible substrate 1, the driving piece 32 needs to drive the bearing film 31 to be pre-fixed in place.

In some embodiments, the bearing film 31 can include a stretching portion beyond the edge of the bearing surface; the driving piece 32 includes a fixture and a roller shaft, the fixture is configured to clamp the edge of the stretching portion and apply a tensile force towards the stretching portion, and the roller shaft is configured to support the stretching portion and change the direction of the tensile force applied to the stretching portion. Exemplarily, the extension direction of the roller shaft is consistent with the extension direction of the edge of the stretching portion, and the fixture has a certain width along the extension direction the edge of the stretching portion, and the fixture can be clamped on a wider edge in the extension direction of the edge of the stretching portion, such that the tensile force acting on the stretching portion is distributed uniformly, and the acting effect is favorable. The driving piece 32 can further include a servo motor, and the servo motor can be in transmission connection with the fixture, to drive the fixture to stretch the edge of the stretching portion of the bearing film 31. The stretching portion of the bearing film 31 can bypass the roller shaft and extend downwards, the edge of the stretching portion is clamped with the fixture, the fixture can be connected with the servo motor, and the servo motor drives the fixture to stretch the edge of the stretching portion. Under the effect of the tensile force, the bearing film 31 can bend and drive the to-be-laminated flexible display panel 100 to bend.

In some embodiments, as shown in FIG. 1, the first press-fitting assembly 4 can include a hydraulic column acting on the flat portion 11 of the flexible substrate 1. In some embodiments, the first press-fitting assembly 4 adopts a hydraulic column, and the hydraulic column can control the distance between the flexible substrate 1 and the cover plate 2 in the laminating process. Before lamination, the flat portion 11 of the flexible substrate 1 is controlled to be close to the middle position of the cover plate 2 through the hydraulic column, such that the middle position of the to-be-laminated flexible display panel 100 is laminated with the cover plate 2, and after full lamination, the flexible substrate 1 is controlled to be far away from the cover plate 2 through the hydraulic column.

In some embodiments, as shown in FIG. 1, the second press-fitting assembly 5 can include an airbag 51 acting on the deformation portion 12 of the flexible substrate 1, an air inlet valve 52 configured to inflate the airbag 51, and an air outlet valve 53 configured to deflate the airbag 51. In some embodiments, the second press-fitting assembly 5 includes the airbag 51, the air inlet valve 52 and the air outlet valve 53. After the middle position of the to-be-laminated flexible display panel 100 is laminated with the cover plate 2, the edge position of the to-be-laminated flexible display panel 100 is laminated with the cover plate 2, the airbag 51 is inflated through the air inlet valve 52 to gradually expand the airbag 51, such that the deformation portion 12 of the flexible substrate 1 gradually changes from the tightened state to the expanded state. An acting force towards the edge position of the cover plate 2 is applied to the edge position of the to-be-laminated flexible display panel 100 through the deformation portion 12 of the flexible substrate 1, to realize lamination between the edge position of the to-be-laminated flexible display panel 100 and the cover plate 2. After lamination, deflation is performed through the air outlet valve 53, the airbag 51 and the flexible substrate 1 gradually recover to their original shapes.

In some embodiments, as shown in FIG. 1 to FIG. 5, a transition area 13 is located between the flat portion 11 and the deformation portion 12 of the flexible substrate 1, and a thickness of a portion, corresponding to the transition area 13, in the airbag 51 can be less than a thickness of another portion in the airbag, thereby being beneficial for expansion of the airbag 51 under force at a thinner place.

In some embodiments, the air inlet valve 52 is a rotatable air inlet valve 52, after the air outlet of the rotatable air inlet valve 52 is rotated, the air outlet blows air directionally towards the portion, corresponding to the transition area 13, in the airbag 51, such that the edge position of the to-be-laminated flexible display panel 100 is fully laminated with the edge position of the cover plate 2.

In some embodiments, when the edge position of the to-be-laminated flexible display panel 100 is laminated with the cover plate 2, firstly the airbag 51 is inflated through the rotatable air inlet valve 52 to gradually expand the airbag 51, such that the deformation portion 12 of the flexible substrate 1 gradually changes from the tightened state to the expanded state, an acting force towards the edge position of the cover plate 2 is applied to the edge position of the to-be-laminated flexible display panel 100 through the deformation portion 12 of the flexible substrate 1, to realize pre-lamination between the edge position of the to-be-laminated flexible display panel 100 and the cover plate 2; afterwards, the air outlet of the rotatable air inlet valve 52 is rotated, to directionally blow air towards the area corresponding to the transition area 13 in the airbag 51 and with the thickness being less than that of the other portions, such that the airbag 51 of the area expands towards the position facing towards the cover plate 2, to ensure the laminating pressure between the edge of the flexible display panel and the inner side of the cover plate 2, such that the laminating effect is better; and finally, the rotatable air inlet valve 52 is closed, the air outlet valve 53 is open, and the airbag 51 keeps deflating, such that the airbag 51 and the flexible substrate 1 gradually recover to their original shapes.

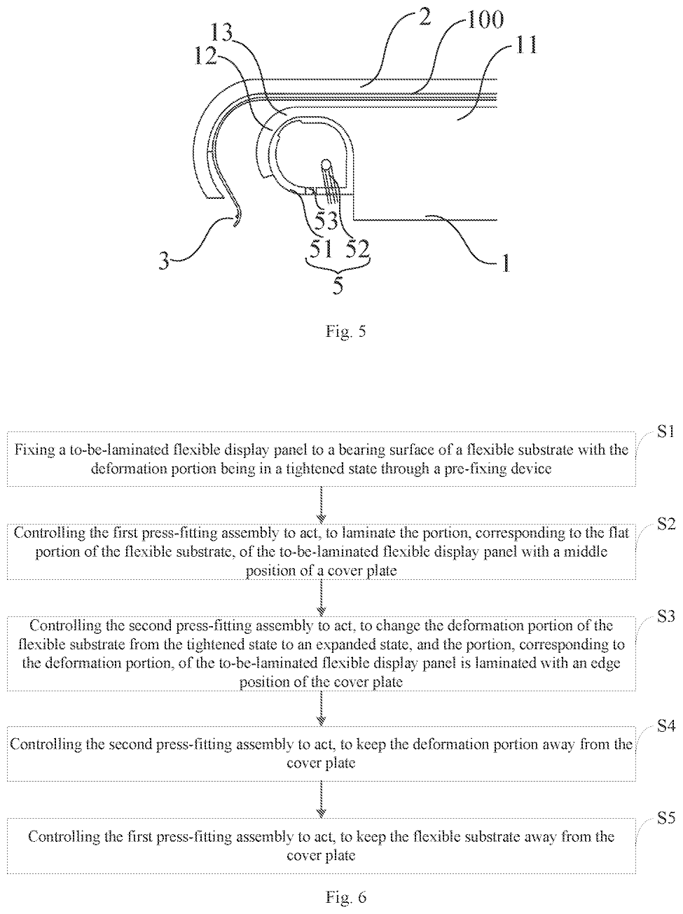

Based on the same inventive concept, embodiments of the present disclosure further provide a lamination method for a flexible display panel, as shown in FIG. 6, the lamination method includes:

S1, fixing a to-be-laminated flexible display panel 100 to a bearing surface of a flexible substrate 1 with the deformation portion 12 being in a tightened state through a pre-fixing device 3, as shown in FIG. 2;

S2, controlling the first press-fitting assembly 4 to act, to laminate the portion, corresponding to the flat portion 11 of the flexible substrate 1, of the to-be-laminated flexible display panel 100 with a middle position of a cover plate 2, as shown in FIGS. 3; and

S3, controlling the second press-fitting assembly 5 to act, to change the deformation portion 12 of the flexible substrate 1 from the tightened state to an expanded state, and the portion, corresponding to the deformation portion 12 of the flexible substrate 1, of the to-be-laminated flexible display panel is laminated with an edge position of the cover plate 2, as shown in FIG. 4, to complete lamination between the flexible display panel and the cover plate 2.

In some embodiments, as shown in FIG. 6, after lamination, the lamination method for a flexible display panel further includes:

S4, controlling the second press-fitting assembly 5 to act, to keep the deformation portion 12 of the flexible substrate 1 away from the cover plate 2; and

S5, controlling the first press-fitting assembly 4 to act, to keep the flexible substrate 1 away from the cover plate 2, as shown in FIG. 5.

In some embodiments, the middle position and the edge position of the to-be-laminated flexible display panel 100 are laminated successively with the first press-fitting assembly 4 and the second press-fitting assembly 5 respectively, and the laminating effect is better, thereby effectively preventing generation of bubbles or cracks by the flexible display panel in the bending area of the large arc inverted cover plate 2, and improving product yield.

In some embodiments, when the second press-fitting assembly 5 includes an airbag 51, a rotatable air inlet valve 52 and an air outlet valve 53, and when the thickness of the portion, corresponding to the transition area 13, in the airbag 51 is less than the thickness of other portions, the process of laminating the edge of the flexible display panel in the above step S3 can adopts the following manner:

firstly, controlling the rotatable air inlet valve 52 to inflate the airbag 51, the airbag 51 is gradually expanded to enable the deformation portion 12 of the flexible substrate 1 to change from a tightened state to the expanded state, to pre-laminated the edge position of the to-be-laminated flexible display panel 100 with the edge position of the cover plate 2; and afterwards, rotating the air outlet of the rotatable air inlet valve 52, and blowing air towards the portion, corresponding to the transition area 13 of the flexible substrate 1, in the airbag 51, such that the edge position of the to-be-laminated flexible display panel 100 is fully laminated with the edge position of the cover plate 2.

In some embodiments, through combining the rotatable air inlet valve 52 and an airbag 51 with the thickness of the portion, corresponding to the transition area 13, of the flexible substrate 1 being less than the thickness of other portions, directional air blowing towards the portion with a smaller thickness of the airbag 51 is realized. Since the portion with a smaller thickness in the airbag 51 is corresponding to the edge of the cover plate 2, and when the cover plate 2 is a large arc inverted cover plate, the portion with a smaller thickness in the airbag 51 is corresponding to the bending area of the large arc inverted cover plate, thereby precisely applying a greater acting force onto the edge bending area of the flexible display panel to ensure the laminating effect and prevent poor lamination.

Obviously, those skilled in the art can make various modifications and variations to the embodiments of the present disclosure without departing from the spirit and scope of the present disclosure. Therefore, the present disclosure is also intended to encompass these modifications and variations thereto so long as the modifications and variations come into the scope of the claims of the present disclosure and their equivalents.

1. A lamination tool for a flexible display panel, comprising:
a flexible substrate, one surface of the flexible substrate serving as a bearing surface;
wherein the flexible substrate comprises:
a flat portion located at a middle position of the flexible substrate; and
a deformation portion located at an edge position of the flexible substrate;
wherein the deformation portion is switched between a tightened state and an expanded state;
a pre-fixing device, configured, when the deformation portion of the flexible substrate is in the tightened state, to:
fix a to-be-laminated flexible display panel on the bearing surface of the flexible substrate; and
bend the to-be-laminated flexible display panel into a shape same as a shape of the bearing surface;
a first press-fitting assembly, configured to act on the flat portion of the flexible substrate to laminate a center of the to-be-laminated flexible display panel with a cover plate; and
a second press-fitting assembly, configured to act on the deformation portion of the flexible substrate and laminate an edge of the to-be-laminated flexible display panel with the cover plate when the deformation portion changes from the tightened state to the expanded state.

2. The lamination tool for the flexible display panel of claim 1, wherein the flexible substrate is a silicone flexible substrate.

3. The lamination tool for the flexible display panel of claim 1, wherein a thickness of the deformation portion is less than a thickness of the flat portion, and the bearing surface of the flexible substrate is a smooth surface.

4. The lamination tool for the flexible display panel of claim 1, wherein the pre-fixing device comprises:
a bearing film; and
a driving piece;
wherein one surface of the bearing film is bonded with the to-be-laminated flexible display panel; and
the other surface of the bearing film is bonded with the bearing surface of the flexible substrate; and
the driving piece is configured to be used in conjunction with the bearing film and drive the bearing film to bend through stretching the bearing film.

5. The lamination tool for the flexible display panel of claim 1, wherein the first press-fitting assembly comprises a hydraulic column acting on the flat portion.

6. The lamination tool for the flexible display panel of claim 1, wherein the second press-fitting assembly comprises:
an airbag acting on the deformation portion;
an air inlet valve configured to inflate the airbag; and
an air outlet valve configured to deflate the airbag.

7. The lamination tool for the flexible display panel of claim 6, wherein a transition area is located between the flat portion and the deformation portion of the flexible substrate; and
a thickness of a portion, corresponding to the transition area, in the airbag is less than a thickness of another portion in the airbag.

8. The lamination tool for the flexible display panel of claim 7, wherein the air inlet valve is a rotatable air inlet valve, and after an air outlet of the rotatable air inlet valve is rotated, the air outlet blows air directionally towards the portion, corresponding to the transition area, in the airbag.

9. A lamination method for a flexible display panel, comprising:
fixing a to-be-laminated flexible display panel to a bearing surface of a flexible substrate with the deformation portion being in a tightened state through a pre-fixing device;
controlling the first press-fitting assembly to act, to laminate the portion, corresponding to the flat portion of the flexible substrate, of the to-be-laminated flexible display panel with a middle position of a cover plate; and
controlling the second press-fitting assembly to act, to change the deformation portion of the flexible substrate from the tightened state to an expanded state, and the portion, corresponding to the deformation portion, of the to-be-laminated flexible display panel is laminated with an edge position of the cover plate.

10. The lamination method for a flexible display panel of claim 9, further comprising:
controlling the second press-fitting assembly to act, to keep the deformation portion away from the cover plate; and
controlling the first press-fitting assembly to act, to keep the flexible substrate away from the cover plate.

11. The lamination method for a flexible display panel of claim 9, wherein the controlling the second press-fitting assembly to act, to change the deformation portion of the flexible substrate from the tightened state to the expanded state, and the portion, corresponding to the deformation portion, of the to-be-laminated flexible display panel is laminated with the edge position of the cover plate, comprises:
controlling a rotatable air inlet valve to inflate an airbag, wherein the airbag is gradually expanded to enable the deformation portion of the flexible substrate to change from the tightened state to the expanded state, to pre-laminated the edge position of the to-be-laminated flexible display panel with the edge position of the cover plate; and
rotating an air outlet of the rotatable air inlet valve, and blowing air directly towards the portion, corresponding to the transition area of the flexible substrate, in the airbag, to fully laminated the edge position of the to-be-laminated flexible display panel with the edge position of the cover plate.

12. The lamination method for a flexible display panel of claim 10, wherein the controlling the second press-fitting assembly to act, to change the deformation portion of the flexible substrate from the tightened state to the expanded state, and the portion, corresponding to the deformation portion, of the to-be-laminated flexible display panel is laminated with the edge position of the cover plate, comprises:
controlling a rotatable air inlet valve to inflate an airbag, wherein the airbag is gradually expanded to enable the deformation portion of the flexible substrate to change from the tightened state to the expanded state, to pre-laminated the edge position of the to-be-laminated flexible display panel with the edge position of the cover plate; and
rotating an air outlet of the rotatable air inlet valve, and blowing air directly towards the portion, corresponding to the transition area of the flexible substrate, in the airbag, to fully laminated the edge position of the to-be-laminated flexible display panel with the edge position of the cover plate.
